(19) United States
(12) Patent Application Publication
(10) Pub. No.: US 2008/0125984 A1
(43) Pub. Date: May 29, 2008

(54) Spatially Assisted Fault Reporting Method, System and Apparatus

(76) Inventors: Veselin Skendzic, Pullman, WA (US); Daniel N. Morman, Pullman, WA (US); George C. Blat, Pullman, WA (US); Ping Jiang, Pullman, WA (US)

Correspondence Address: COOK, ALEX, MCFARRON, MANZO, CUMMINGS & MEHLER LTD, SUITE 2850, 200 WEST ADAMS STREET, CHICAGO, IL, 60606, US

(21) Appl. No.: 11/534,898

(22) Filed: Sep. 25, 2006

(51) Int. Cl. G01R 31/00; G06F 19/00

(52) U.S. Cl. 702/59

(57) ABSTRACT

Methods and systems for spatially assisted fault reporting in a distribution system. Typical steps of the methods may include determining the location of the fault or the distance to the fault, generating and storing a plurality of waypoints representative of the route of the distribution system, processing the plurality of waypoints, determining spatial coordinates of the fault, generating a fault report, and communicating the fault report. The waypoints may be contained within an XML file which is compressed with a compression algorithm prior to sending and which is decompressed prior to use at a receiving end to create a visual template or overlay for displaying the fault information

### FIELD OF THE INVENTION

The present invention relates generally to methods for reporting and for visually displaying a fault or anomaly in a distribution system having spatial coordinates.

### BACKGROUND OF THE INVENTION

The algorithms for locating and identifying faults or other anomalies are well known in the art and are used extensively in a variety of distribution systems. Such distribution systems include, but are not limited to, road-based transportation systems, pipeline-based transportation or distribution systems (such as for gas, oil or water), electric power systems (including generation, transmission and distribution of electric power), communication systems (including fiber-optic or wire-based), and the like.

Distribution system faults in electric power systems are commonly detected by a variety of individual fault detection devices. Such devices may operate autonomously or in small groups and are typically spatially distributed throughout the system. However, the large distance spanned by some distribution or transportation systems may be a prominent distinguishing characteristic.

Due to the distance encompassed by the system and number of the fault detection locations or nodes within the system, it is often advantageous to communicate the information about any fault to a central location. Current reporting methods include various supervisory control and data acquisition (SCADA) based alarm collection systems, text messaging, automated telephone-based voice messaging For example, a model SEL 3010 event messenger, which is commercially available from Schweitzer Engineering Laboratories of Pullman, Wash., may be used to report information about a fault in an electrical distribution system.

Currently deployed fault reporting methods often lack the means to communicate the fault information in terms of a geographic location, such as with coordinates that define the geographic location of interest Current methods are also unable to efficiently integrate with the state of the art. Geographic Information Systems (hereafter, “GIS system”). Preferably, the GIS system should be capable of displaying the communicated fault information in the visual form, such as on a map of the terrain, and to correlate such information with multiple data overlays, such as with overlays including roads, hydrology, services and infrastructure.

A general object of the present invention is to therefore provide improved methods and systems for reporting and for visually displaying a fault in a distribution system by using spatial coordinates.

Another object of the present invention is to provide improved systems and methods that utilize the GIS system for displaying the communicated fault information in a visual form, such as on a map of the terrain or as overlying templates.

A further object of the present invention is to provide improved systems and methods for reporting and for visually displaying a fault in a distribution system that correlates the fault information with multiple data overlays, such as with overlays including roads, hydrology, services and/or infrastructure.

### SUMMARY OF THE INVENTION

The present invention is directed to a method for spatially assisting the reporting of a fault in a distribution system. Typically, a method may include the steps of determining the location of the fault or the distance to the fault, generating and storing a plurality of waypoints representative of the route of the distribution system, processing the plurality of waypoints, determining spatial coordinates of the fault, generating a fault report, and communicating the fault report. Further steps of the method may include subsequently displaying the fault information by using a geographic information system, displaying an automated analysis of information included in the fault report, storing the waypoints in a remote device, pre-calculating the distance between waypoints, and communicating the pre-calculated waypoints to the remote device.

In accordance another aspect of the present invention, the step of communicating the pre-calculated waypoints to the remote device may include sending the fault report via a communication mechanism, such as an email system message or as an email message attachment. The waypoints may be contained within an XML file and the methods may include the additional steps of compressing the XML file with a compression algorithm prior to sending, and decompressing or expanding the compressed XML file prior to use at a receiving end. The compression algorithm may be any lossless compression one, some popular examples being zlib, zip, 7z, rar, arj and bzip2. The distribution system may be an electric power distribution system, a pipeline-based oil or gas distribution system, or the like.

The present invention is further directed to a spatially-assisted fault reporting system for a distribution system. The fault reporting system may include a fault detection device for detecting the fault and for determining the location of the fault, a geographic information system for visually displaying the location of the fault, and a communication system for transmitting information about the fault from the fault detection device to the geographic information system. Preferably, the geographic information system displays an automated analysis of the transmitted fault information. The distribution system may be an electric power distribution system, a pipeline-based oil or gas distribution system, or the like.

The geographic information system may generate a plurality of waypoints representative of the route of the distribution system. The fault detection device determines the location of the fault or the distance to the fault. The geographic information system processes the plurality of waypoints and determines spatial coordinates of the fault.

The communication system of the fault reporting system may include email messaging for sending the transmitted fault information as an email or as an email attachment. The fault detection device of the fault reporting system stores the plurality of waypoints in an XML file, compresses the XML file with a lossless compression algorithm, such as zlib, zip, 7z, rar, arj, bzip2 or similar, and communicates the XML file to the geographical information system The geographical information system decompresses the XML file with the decompression algorithm which matches the compression algorithm of the file.

### BRIEF DESCRIPTION OF THE DRAWINGS

The invention, together with its objects and the advantages thereof, may best be understood by reference to the following description taken in conjunction with the accompanying drawings, in which like reference numerals identify like elements in the figures, and in which:

FIG. 1 is a template created by the present invention illustrating a fault in a power distribution line and which contains information about the fault for display to user.

FIG. 2 is a template also created by the present invention illustrating a substation with a fault reporting device which determines the location of a fault shown in FIG. 1 in the power distribution line and which also reports information about the fault to a user.

FIGS. 3A-3C collectively form a typical file generated by the fault reporting devices in FIGS. 1 and 2 and this file may be sent using a stand alone file transmission protocol such as FTP, DNP-3, HTTP or IEC 61850 file services, as an email or as an email attachment in accordance with the present invention

FIG. 4 is another template created by the present invention, similar to the template shown in FIG. 1, but which illustrates multiple faults at multiple points along the power distribution line.

FIG. 5 illustrates a fault reporting system in accordance with the present invention.

FIG. 6 illustrates an apparatus for fault reporting in accordance with the present invention.

### DESCRIPTION OF THE PREFERRED EMBODIMENTS

It will be understood that the present invention may be embodied in other specific forms without departing from the spirit thereof. The present examples and embodiments, therefore, are to be considered in all respects as illustrative and not restrictive, and the invention is not to be limited to the details presented herein.

The present invention makes it possible for a fault reporting device to identify a location of the fault, such as with Global Positioning System (GPS) coordinates, and to use modern World Wide Web/Internet-based communication methods to send the information about the fault to an interested user. Main technologies used are email, email attachments, XML-based resource topology description and GIS system-based terrain visualization.

The present invention can be deployed in a wide range of autonomous embedded systems, such as in protective relays in electrical power systems The present invention may also be used in other types of distribution systems which have fixed portions at identifiable GPS coordinates, such as in oil or gas distribution systems. Other types of anomalies, malfunctions, disturbances, and the like, may also be reported in addition to, or in lieu of, faults. Moderate computational resources are required to implement the present invention. Moreover, the present invention does not place undue burdens on the embedded system which reports the fault.

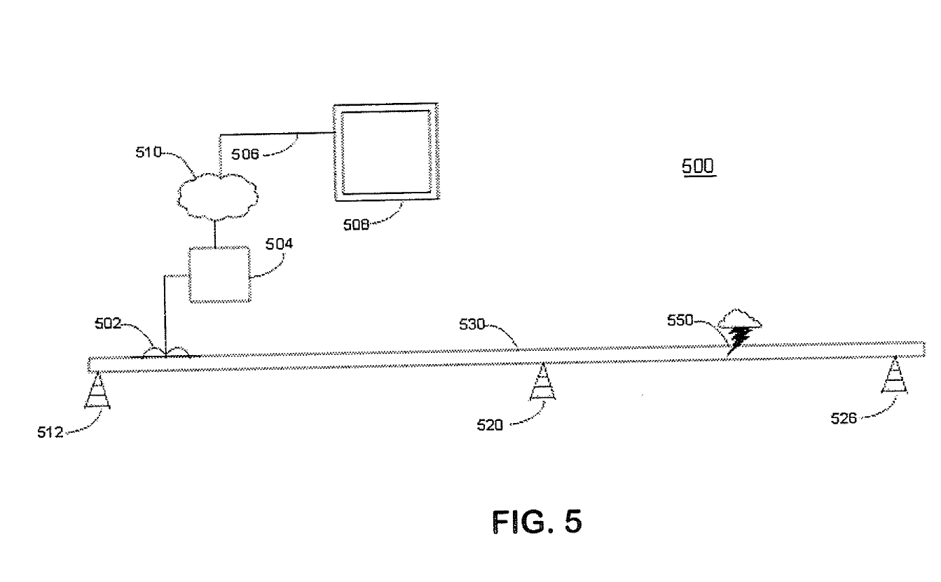

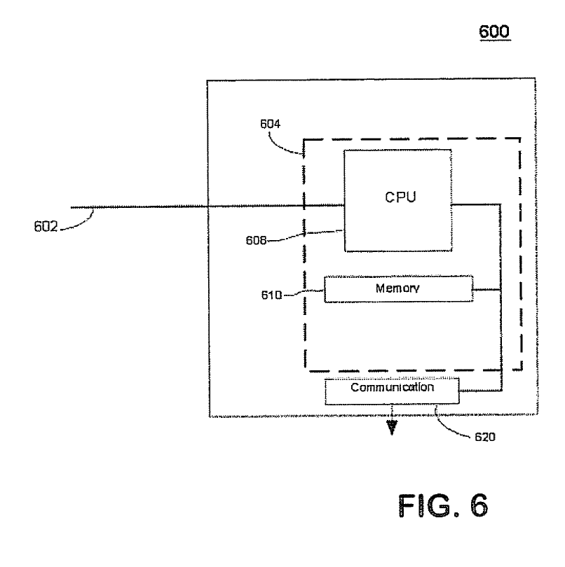

A system for reporting faults is generally illustrated in FIG. 5 In this illustration, the system for reporting faults 500 includes a fault detection device 504 for detecting a fault 550 (using, for example, a sensor 502 on the distribution system 530) and for determining the location of the fault. The fault 550 may occur on a distribution system 530 as described herein The system for reporting faults 500 further includes a communication system 506 for transmitting information about the fault 550 from the fault detection device 504 to a geographic information system 508.

As described in more detail herein, the fault detection device 504 may include information, such as geographical coordinates, for waypoints 512-526 along the route of the distribution system 530. The waypoints 512-526 may include, for example, power transmission line towers, pumping stations on pipeline-based distribution systems, and the like.

The communication system 506, as described in more detail herein, may communicate fault information via a network 510, such as via the internet or any other suitable medium. In one preferred embodiment, the fault information is communicated by email.

In the illustrated embodiment shown in FIG. 5, the fault 550 occurred between waypoints 520 and 526. The fault detection device 504 includes the geographical coordinates of each of the waypoints 512-526, and can use these coordinates to calculate the linear distances between each waypoint. In one embodiment, the fault detection device 504 calculates the total distance to the fault 550. Using the total distance to the fault 50 and a sum of the distances between the waypoints up to the fault, the geographical coordinates of the fault may be calculated. The coordinates of the fault may then be included in the fault information communicated to the geographical information system 508. These coordinates may be used to visually display a pinpoint location of the fault using the geographical information system 508. The calculation of the distance to the fault may also include an estimated error, which may also be included in the fault information communicated to the geographical information system 508.

In accordance with one aspect of the present invention, methods and systems for spatially-assisted fault reporting utilize a short XML file. XML is an acronym for Extensive Markup Language, which is an open standard developed by the World Wide Web Consortium. In the present invention, this XML file may contain absolute coordinates, which may also be referred to as waypoints, describing distribution system topology, information about the fault and the location of the fault. Location of the fault may further include tolerance or uncertainty bands and other information of interest, such as altitude and the like.

For example, information about the fault may further include reporting device identification, reporting device location, fault characteristics, and the time of the fault. Prior to sending the fault information to the GIS system, the fault reporting device may compress the XML file with a lossless compression algorithm, such as with a zlib, zip, 7z, rar, arj, bzip2 or similar. Such lossless compression algorithms are well known in the art.

The XML file is preferably self contained and can be communicated through a variety of communications systems. It can be sent in the form of attachment to other fault reporting methods, such as by electronic mail, commonly known as email. The XML file may contain additional links to other resources, such as a web-based link back to the reporting device, device manufacturer website, transportation system operator or other support links of interest.

In one embodiment, the described XML attachment may be compliant with Keyhole Markup Language (KML). KML is an XML grammar and file format for modeling and storing geographic features such as points, lines, images, and polygons for display in Google Earth™ mapping service. A KML file is processed by Google Earth™ mapping service in a similar manner to the processing of HTML files by web browsers. Like HTML, KML has a tag-based structure with names and attributes used for specific display purposes. For example, icons or labels may be used to identify locations on the surface of the Earth. Thus, Google Earth™ mapping service acts as a browser of KML files.

One example of such a fault reporting system could be a distance relay equipped with the XML-based data template. Such templates may contain all of the information necessary for creation of the fault report, including the GPS coordinates of the transmission line corridor, the GPS location of the distance relay protecting the line, the distance vector describing the length of the line and the incremental distance vector. For example, the distance vector may be calculated ahead of time and stored either in incremental or in cumulative form, or calculated locally by the fault reporting device when and as needed.

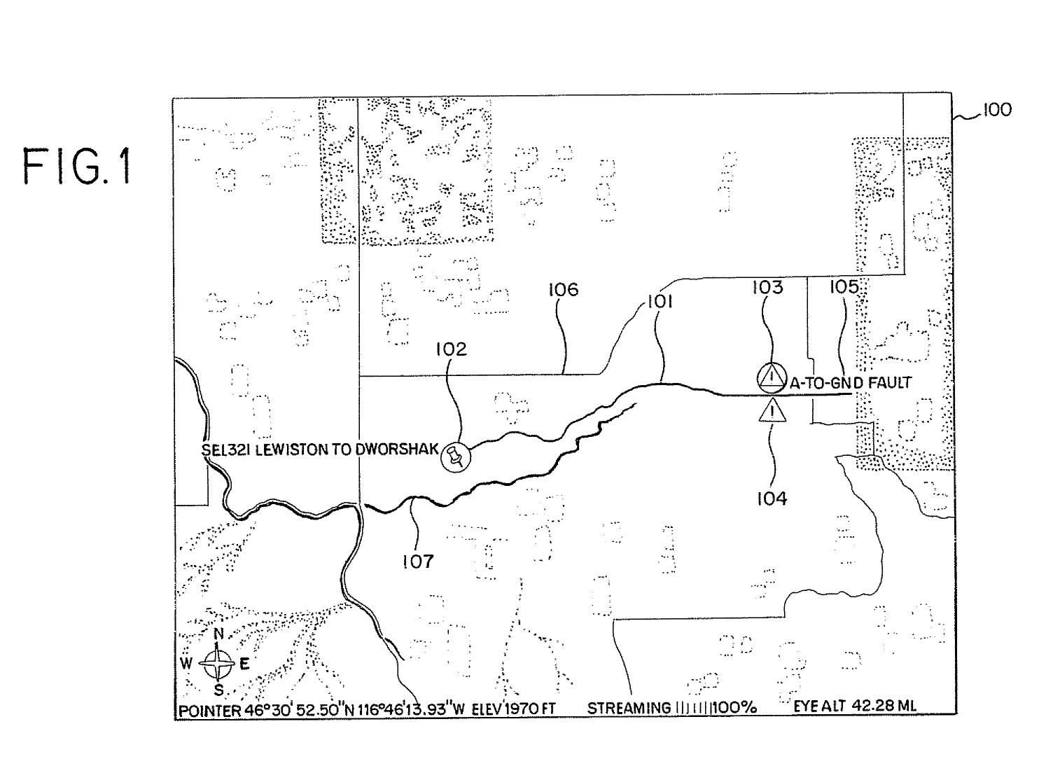

In view of the foregoing general description, a specific example using the present invention will now be considered. FIG. 1 illustrates a typical visual template 100. One or more electrical distribution lines 101 and a fault reporting device 102 are shown in the template. In this example, a fault of the A-phase to ground has occurred at specific location or waypoint as indicated by an icon 103. For example, this icon may be an enlarged red dot with a yellow safety triangle and an exclamation point included in the icon. An icon 104 opposite to icon 103 may be a pointer, which may include another yellow safety triangle and exclamation point. A legend 105 may provide further description, such as “A-to-GND Fault” (A-phase to ground fault) in this example. Visual template 100 may further include various other features, such as roads 106, rivers 107 and other topographical features present in the depicted area.

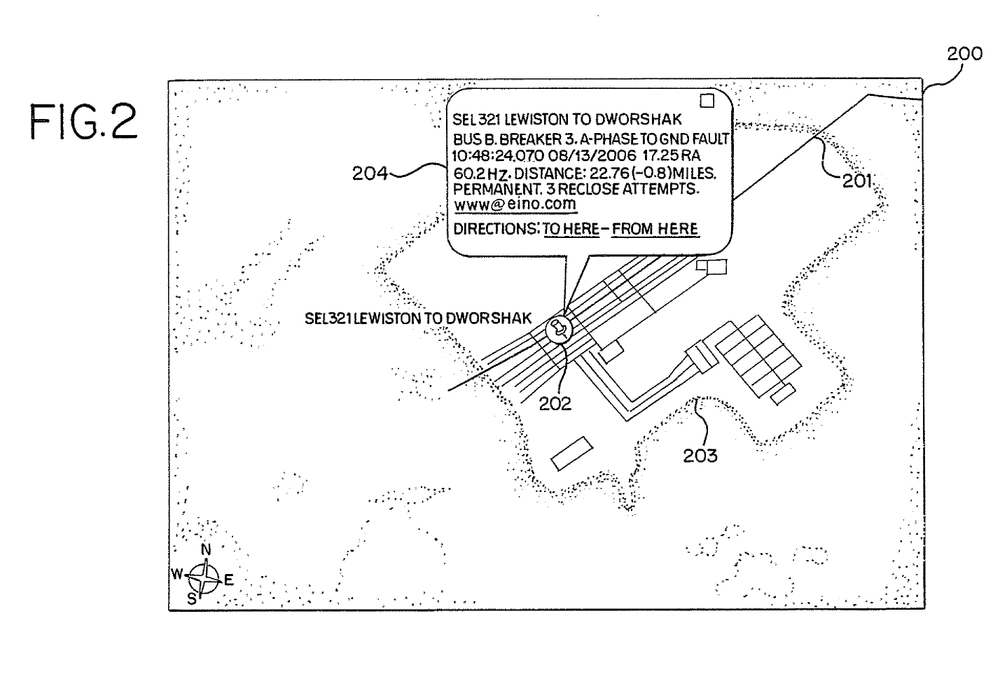

Another visual template 200 in FIG. 2 may be utilized to illustrate the substation 203 associated with a fault on one or more electrical distribution lines 201. In this example, a reporting device 202 at the substation 203 has determined that a fault exists on one of the distribution lines 201. As indicated in an information balloon 204, reporting device 202 has determined that an A-phase to ground fault has occurred at an identified time and date, that the fault is 17.25 kA and 60.2 Hz at a distance of 22.78 (±0.8) miles, that the fault is permanent and that three reclose attempts were unsuccessful

In order for the reporting device 102 in FIG. 1 or 202 in FIG. 2 to perform its reporting function, the reporting device needs to identify information about the fault. This information about the fault may include the distance to the fault, the type of fault, the time of the fault, the current level and any other related or desirable information. For example, the distance to the fault may be expressed as a percentage of the line length or in as a unit length, such as miles or kilometers, between the reporting device and the fault. The fault reporting device 102 or 202 may also determine the cumulative distance vector and start adding the distances until reaching the calculated fault location, use the index of the last point to extract the fault GPS coordinates of the fault from the waypoint list, compose a message by filling in strategic locations in the XML file template, and send the email with the newly composed message or as an attachment to the message However, before the fault reporting device 102 or 202 can compose an email message, additional information may need to be available. For example, such preliminary information may include the line length, the GPS waypoints list describing the line corridor and preferably starting at the location of the fault reporting device, a list of distances between the GPS waypoints which may also be referred to as the “distance vector”, and email system information. The email system information may include a list of recipients, a POP server address, a “From” line, a “Subject” line, and default text such as email contents with summary information about the fault

Most of the above GPS information can be contained in a single XML file template. This template will be prepared ahead of time, and will be created specifically for every relay, thus containing only parameters pertinent to the particular relay location including the line protected by the relay. Template files could be created by the customer or supplied by the vendor as a separate service Additional enhancements such as aerial photograph inserts, GPS coordinate imports and the like can be accommodated as desired or required.

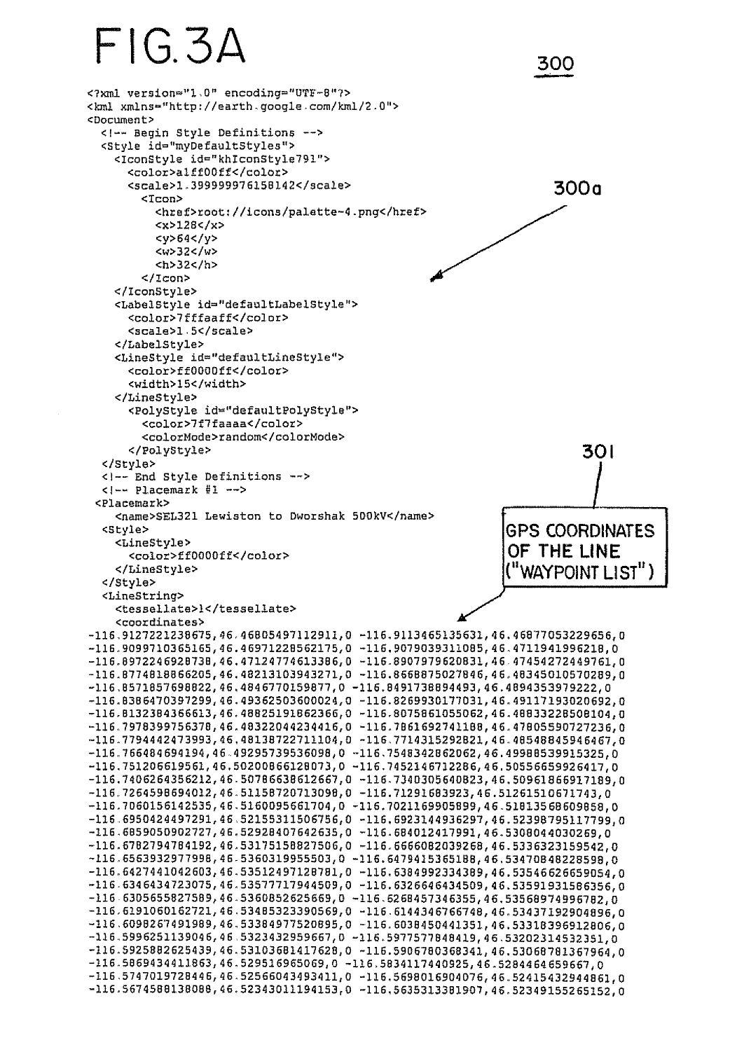

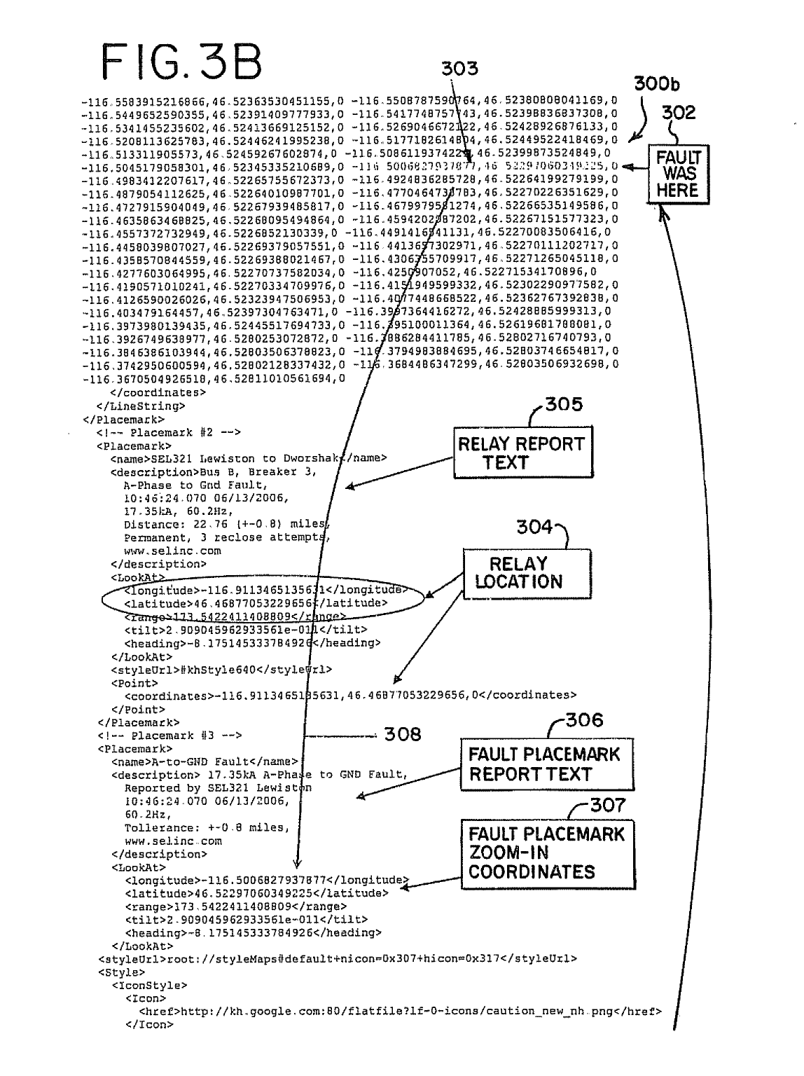

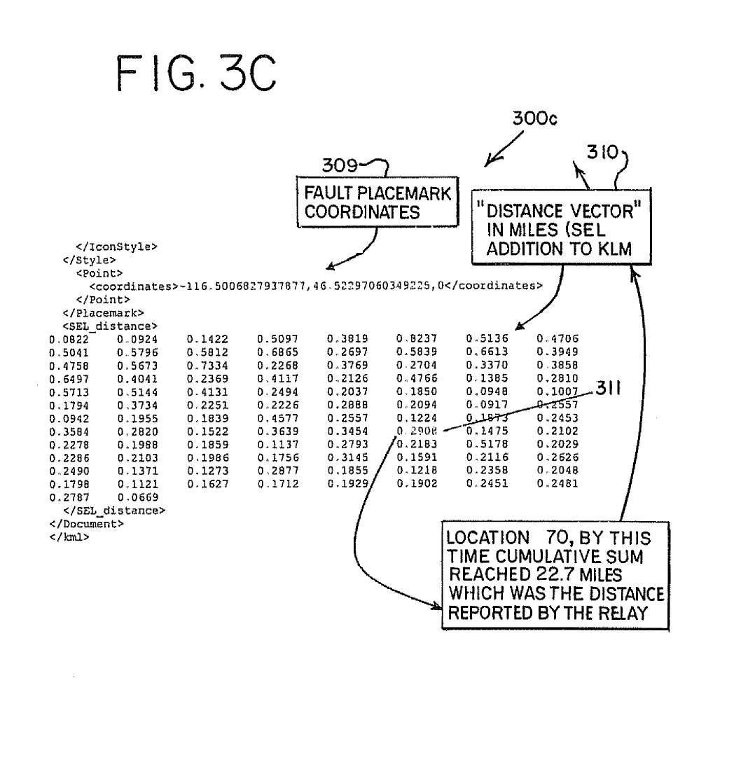

FIGS. 3A-3C illustrate an example of an XML file, generally designated 300, that may be used by the fault reporting device 102 or 202 in FIGS. 1 or 2 to report a fault or other problem in a distribution line. A first portion 300a of the XML file 300 is in FIG, 3A, a second portion 300b is in FIG, 3B and third portion 300c is in FIG. 3C. Beginning at box 301 in FIG. 1 are about 50 lines of GPS waypoints on FIGS. 3A-3B that define the location of the distribution line of interest, such as line 101 in FIG. 1 or line 201 in FIG. 2. A box 302 in FIG. 3B identifies the waypoint 303 at which a fault occurred in this example. The GPS coordinates of the fault reporting device are indicated by box 304. Using waypoint 303 and its GPS coordinates, the fault reporting device determines the distance between the fault reporting device and the fault. In this example, the fault reporting device 102 or 202 prepares a report, as indicated by box 305, ““Bus B, Breaker 3, A-Phase to GND Fault, 10.46:24,070 Jun. 13, 2006, 17.35 kA, 60.2 Hz, Distance. 22.76 (±08) miles, Permanent, 3 reclose attempts, www.selinc.com”, Most of this report text is again repeated in the XML file 300 at the location indicated by box 306. The waypoint or GPS coordinates of the fault are again repeated, as indicated in the XML file 300 by box 307 and by arrow 308 in FIG. 3B and by box 309 in FIG, 3C. As seen in FIG. 3C, the fault reporting device calculates the distance vector (box 310 in FIG. 3C) by summing up the distances between each of the waypoints between the fault reporting device and the location #70 311, which is the waypoint at which the exemplary fault occurred.

As shown in the above example FIGS. 3A-3C, most of the necessary information can be contained in a single XML file which can be automatically edited by the fault reporting application. If desired, a template file can be split into multiple files/sections in order to simplify the required reporting application. The GIS system then uses and translates the information from the XML file to create the template or overlays of FIG. 1 or 2 which visually display the fault information detected and reported by fault reporting devices 102 or 103.

The displays 100 and 200 shown in FIGS. 1 and 2 use the Keyhole Markup Language (KML) to store, process and send information about the fault KML syntax and other details can be found at: http://earth.google.com/kml/kml intro.html

The waypoint list 301 in FIGS. 3A-3B may be generated by using Google Earth Plus “Add Path” function. The “distance vector” may be created by using a simple GPS coordinate based distance vector calculation script written in Matlab. Any additional line length created by elevation change can be accounted for by simply stretching or scaling the physical distance until it matches electrical line length or actual relay setting. Additional enhancements are easily possible by using more advanced features of KML.

The present invention thus provides an email attachment based visualization method capable of displaying the approximate geographic location of a power system fault. GIS database visualization is accomplished by using Google Earth™ mapping service and an XML file attachment. The XML file attachment may be largely created ahead of time and used as a template, thereby making it possible for the relay, or associated fault reporting device, to determine GPS coordinates of the fault, to modify pertinent file sections, such as about 10 percent of the file, and to send the resulting file as an email attachment The system may then create the visualization examples which are shown in FIGS. 1, 2 and 4.

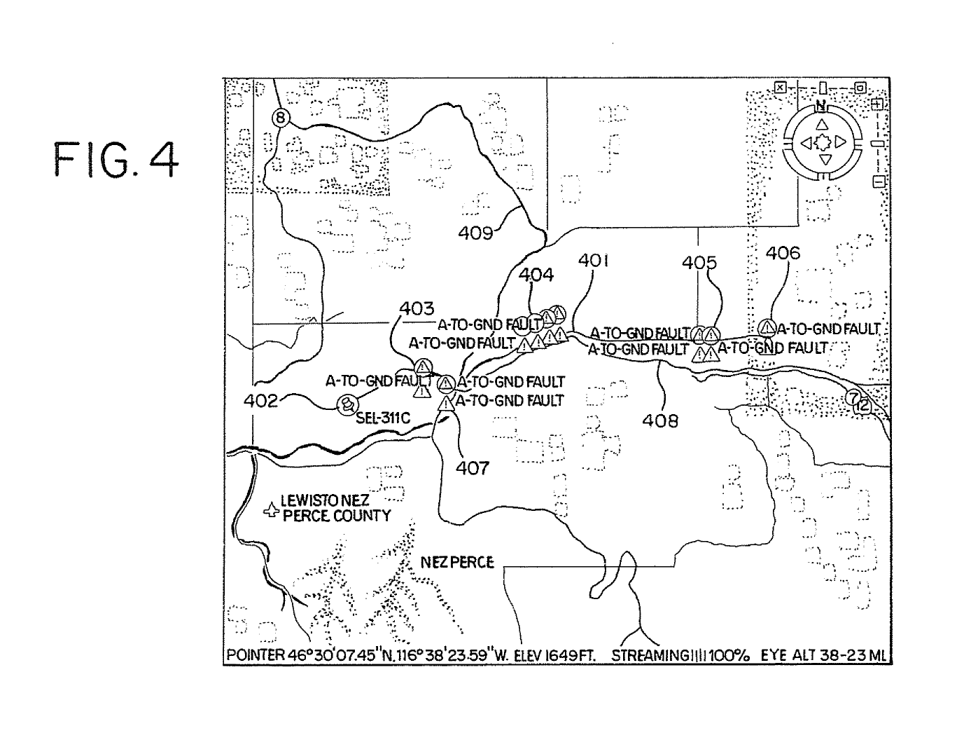

The present invention also contemplates reporting multiple faults occurring in a distribution line over an extended period of time. FIG. 4 illustrates an exemplary visual template 400. In this example, a reporting device 402 has determined that multiple faults have occurred in a distribution line 401, including at locations 403, 404, 405 and 406. Thus, the fault reporting device 402 will prepare a report consisting of an XML file similar to the file 300 in FIGS. 3A-3C, but with multiple reported faults at each of the locations 403-406. The fault reporting device 402 will then send the XML file as an email attachment, which the system will utilize to create the visual template 400.

In another embodiment of the present invention, a template file can be used to construct a web-based hyperlink for displaying the fault location on a web-based GIS system, such as with a Google Maps™ Application Program Interface (API).

An apparatus for fault reporting 600 in accordance with an embodiment of the present invention is illustrated in FIG, 6 As illustrated, the apparatus 600 includes an input 602 configured to receive data relating to the distribution system. The data is transmitted to the microcontroller 604. The microcontroller 604 may include a CPU or microprocessor 608 and a memory 610. As will be appreciated by those skilled in the art, other suitable microcontroller configurations may be utilized. Further, although discussed in terms of a microcontroller, it should be noted that the embodiments presented and claimed herein may be practiced using an FPGA (field programmable gate array) or other equivalent.

The memory 610 may include information such as the locations of the waypoints, distances between the waypoints, the template XML file, and the like. The CPU or microprocessor 608 identifies the fault and generates the fault report to be communicated via the communication channel 620. These processes may correspond with any of the previously described processes. Accordingly, the communication channel may include a serial port, an Ethernet port, a fiber optic port, radio transmission, infrared transmission, and the like.

It is understood that a person skilled in the art may separate the template file into multiple files or multiple templates. Such multiple files or multiple templates may be assembled together during the fault report creation process Such modifications are considered to be included within the scope of this invention.

While particular embodiments of the invention have been shown and described, it will be obvious to those skilled in the art that changes and modifications may be made therein without departing from the invention in its broader aspects.

1. A method for reporting a fault in a distribution system, the method comprising the steps of:
determining a location of the fault;
generating and storing a plurality of waypoints representative of a route of the distribution system;
generating a fault report; and
communicating the fault report.

2. The method for reporting a fault in accordance with claim 1, wherein the location of the fault is determined using a distance to the fault and the plurality of waypoints.

3. The method for reporting a fault in accordance with claim 2, wherein the distribution system is an electric power transmission system, and the distance to the fault is calculated using an impedance of a power transmission line.

4. The method for reporting a fault in accordance with claim 1, the method comprising the additional step of:
subsequently displaying the location of the fault information by using a geographic information system.

5. The method for reporting a fault in accordance with claim 1, the method comprising the additional step of:
displaying an automated analysis of information included in the fault report.

6. The method for reporting a fault in accordance with claim 1, wherein the distribution system is an electric power system.

7. The method for reporting a fault in accordance with claim 6, wherein the electric power system is an electric power transmission system.

8. The method for reporting a fault in accordance with claim 6, wherein the electric power system is a pipeline-based distribution system.

9. The method for reporting a fault in accordance with claim 1, wherein the distribution system is a communication system.

10. The method for reporting a fault in accordance with claim 8, wherein the communication system is fiber-optic or wire-based.

11. The method for reporting a fault in accordance with claim 1, wherein the distribution system is a road-based transportation system.

12. The method for reporting a fault in accordance with claim 1, wherein the step of communicating the fault report comprises:
sending the fault report as an email system message or as an email message attachment.

13. The method for reporting a fault in accordance with claim 1, wherein the step of communicating the fault report comprises:
sending the fault report via a stand alone transmission protocol.

14. The method for reporting a fault in accordance with claim 1, said method comprising the additional steps of:
storing the waypoints in a remote device; and
containing the waypoints in an XML file.

15. The method for reporting a fault in accordance with claim 1, the method comprising the additional steps of:
pre-calculating a distance between the waypoints; and
communicating the distance between the waypoints to a remote device.

16. The method for reporting a fault in accordance with claim 14, the method comprising the additional steps of:
compressing the XML file with a compression algorithm; and
decompressing or expanding the compressed XML file prior to use at a receiving end.

17. The method for reporting a fault in accordance with claim 16, the method comprising the additional step of:
selecting the compression algorithm from the group consisting of zlib, zip, 7z, rar, arj and bzip2.

18. A fault reporting system for a distribution system, the fault reporting system comprising:
a fault detection device for detecting a fault and for determining a location of the fault;
a geographic information system for visually displaying the location of the fault; and
a communication system for transmitting information about the fault from the fault detection device to the geographic information system.

19. The fault reporting system in accordance with claim 18, wherein the geographic information system displays an automated analysis of the transmitted fault information.

20. The fault reporting system in accordance with claim 18, wherein the distribution system is an electrical power system.

21. The fault reporting system in accordance with claim 20, wherein the electrical power system is an electrical power transmission system.

22. The fault reporting system in accordance with claim 18, wherein the distribution system is a pipeline-based distribution system.

23. The fault reporting system in accordance with claim 18, wherein the distribution system is a communication system.

24. The fault reporting system in accordance with claim 23, wherein the communication system is fiber-optic or wire-based.

25. The fault reporting system in accordance with claim 18, wherein the distribution system is a road-based transportation system.

26. The fault reporting system in accordance with claim 18, the communication system including email messaging for sending the transmitted fault information as an email or an email attachment.

27. The fault reporting system in accordance with claim 18, wherein the fault detection device determines the location of the fault.

28. The fault reporting system in accordance with claim 27, wherein the location of the fault is determined using a distance to the fault and a plurality of waypoints representative of a route of the distribution system.

29. The fault reporting system in accordance with claim 28, wherein the distribution system is an electric power distribution system, and the distance to the fault is determined using an impedance of the electric power transmission system.

30. The fault reporting system in accordance with claim 18, wherein the geographic information system generates a plurality of waypoints representative of the route of the distribution system.

31. The fault reporting system in accordance with claim 30, wherein the geographic information system processes the plurality of waypoints and determines spatial coordinates of the fault.

32. The fault reporting system in accordance with claim 30, wherein the fault detection device stores the plurality of waypoints in an XML file.

33. The fault reporting system in accordance with claim 32, wherein the fault detection device communicates the XML file to the geographical information system.

34. The fault reporting system in accordance with claim 33, wherein said fault detection device compresses the XML file with a compression algorithm and the geographical information system decompresses the XML file.

35. The fault reporting system in accordance with claim 34, wherein said fault detection device compresses the XML file with a compression algorithm selected from the group consisting of zlib, zip, 7z, rar, arj and bzip2.

36. An apparatus for reporting a fault in a distribution system, the apparatus comprising:
a fault detection apparatus for detecting a fault;
a memory comprising geographical information relating to a route of the distribution system;
a processor for determining a location of the fault, and for generating a fault report comprising the location of the fault; and,
a communication system for transmitting the fault report.

37. The apparatus for reporting a fault in accordance with claim 36, wherein the graphical information relating to the route of the distribution system includes a plurality of waypoints along the route of the distribution system.

38. The apparatus for reporting a fault in accordance with claim 37, wherein the location of the location of the fault is calculated using the waypoints and the distance to the fault.

39. The apparatus for reporting a fault in accordance with claim 36, wherein the distribution system is an electric power transmission system, and the distance to the fault is calculated using an impedance of a power transmission line.

40. The apparatus for reporting a fault in accordance with claim 36, wherein the fault report further comprises the graphical information relating to the route of the distribution system.

41. The apparatus for reporting a fault in accordance with claim 40, wherein the fault report comprises a configuration for use with a graphical information system.

42. The apparatus for reporting a fault in accordance with claim 41, wherein the configuration comprises Keyhole Markup Language.

43. The apparatus for reporting a fault in accordance with claim 36, wherein the communication system comprises a configuration for transmitting the fault report as an email system message or as an email message attachment.

44. The apparatus for reporting a fault in accordance with claim 36, wherein the communication system comprises a configuration for transmitting the fault report using a stand alone file transmission protocol.

45. The apparatus for reporting a fault in accordance with claim 37, wherein the graphical information further comprises a distance between the waypoints.

46. The apparatus for reporting a fault in accordance with claim 36, wherein the distribution system is an electric power transmission system.

47. The apparatus for reporting a fault in accordance with claim 36, wherein the distribution system is a pipeline-based distribution system.

48. The apparatus for reporting a fault in accordance with claim 36, wherein the distribution system is a communication system.

49. The apparatus for reporting a fault in accordance with claim 48, wherein the communication system is fiber-optic or wire-based.

50. The apparatus for reporting a fault in accordance with claim 36, wherein the distribution system is a road-based transportation system.

51. A fault reporting system for a distribution system, the fault reporting system comprising:
means for determining the location of the fault or the distance to the fault;
means for generating and storing a plurality of waypoints representative of the route of the distribution system;
means for processing the plurality of waypoints;
means for determining spatial coordinates of the fault;
means for generating a fault report; and
means for communicating the fault report.
